(19) United States
(12) Patent Application Publication
(10) Pub. No.: US 2007/0145480 A1
(43) Pub. Date: Jun. 28, 2007

(54) THIN FILM TRANSISTOR, ELECTRODE THEREOF AND METHOD OF FABRICATING THE SAME

(76) Inventors: Hsiang-Yuan Cheng, Taipei City (TW); Yi-Kai Wang, Hsinchu City (TW); Tarng-Shiang Hu, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,562

(22) Filed: Apr. 7, 2006

(30) Foreign Application Priority Data
Dec. 26, 2005 (TW) 94146475

(51) Int. Cl. H01L 27/12

(52) U.S. Cl. 257/347

(57) ABSTRACT

A method of forming an electrode of a semiconductor device is provided. A material layer comprising an organo-metallic compound is first formed on a substrate. Thereafter, an electrode is formed by irradiating the material layer through utilizing the heating property of laser. Next, the material layer is patterned by utilizing the photochemical or heating properties of laser using a laser. Because laser irradiation is substituted the traditional heating way, it can reduce process temperature. Furthermore, because the laser is used for patterning the material layer to form the electrode, therefore an electrode pattern with a greater precision may be obtained compared to that obtained by using the photolithography process.

### CROSS-REFERENCE TO RELATED APPLICATION

This application claims the priority benefit of Taiwan application serial no. 94146475, filed on Dec. 26, 2005. All disclosure of the Taiwan application is incorporated herein by reference.

### BACKGROUND OF THE INVENTION

1. Field of the Invention

The present invention relates to a method of fabricating an electrode, and more particularly to a thin film transistor, an electrode and a method of fabricating the same.

2. Description of Related Art

Generally, the electrode is manufactured by evaporation or sputtering process. However, the manufacturing cost of evaporation or sputtering is high, and due to the use of vacuum equipments and photolithography process, and the resolution of the photolithography process is limited, and also, the acid and alkaline solution in the photolithography process may damage material layers such as organic semiconductor layers. Therefore, recently, an ink-jet printing technique has been developed, which suitable for coating. However, due to the hydrophilic/hydrophobic property and capillarity of organic material and the substrate, the resolution is limited.

### SUMMARY OF THE INVENTION

An object of the present invention is to provide an electrode of a semiconductor device for enhancing the resolution of the device.

Another object of the present invention is to provide a thin film transistor (TFT) with an electrode formed with high precision using a laser such that the reliability and the performance of the TFT are enhanced.

Yet another object of the present invention is to provide a method of forming an electrode of a semiconductor device using a laser so that the photolithography process may be avoided. Thus, not only the fabrication throughput is increased but also the overall fabrication cost of the semiconductor device may be effectively reduced and the reliability of the semiconductor device may be effectively promoted.

The present invention provides an electrode of a semiconductor device comprising an organo-metallic compound, wherein the insulating property of the organo-metallic compound is transformed into a conductive property using a laser.

The present invention also provides a structure of a thin film transistor comprising a substrate, a gate electrode, a gate insulator, a semiconductor layer, a source electrode and a drain electrode, wherein the semiconductor layer may be disposed over or under the source electrode and the drain electrode. The source electrode and the drain electrode may be disposed over or under both sides of the gate electrode respectively. The gate insulator separates the gate electrode from the semiconductor layer, the source electrode and the drain electrode. The thin film transistor is characterized in that the gate electrode and/or source electrode and the drain electrode comprise an organo-metallic compound whose insulating property is transformed into a conductive property by using a laser.

According to an embodiment of the present invention, the metal elements of the above organo-metallic compound comprise at least one of the groups comprising Ib, IIb, VIIIa Group elements, indium, tin, antimony, lead, bismuth or any combination thereof.

According to an embodiment of the present invention, the material of the semiconductor layer comprises at least one of the groups comprising small molecule, oligomer, polymer, or any other organic substance which can be transformed into semiconductor property.

According to an embodiment of the present invention, the substrate comprises at least one of the groups comprising Si wafer, glass substrate, metal substrate or plastic substrate.

According to an embodiment of the present invention the material of the gate insulation layer comprises organic material or inorganic material, wherein the organic material includes PMMA, PVA, PVP, PI or the like and the inorganic material includes SiOx, SiNx, LiF, or the like.

The present invention also provide a method for forming an electrode of a TFT comprising forming a material layer on a substrate, wherein the material layer comprises an organo-metallic compound layer or nanometer material coating; forming an electrode by locally activating the material layer through utilizing the heating property of a laser; and patterning the material layer by utilizing the photochemical or heating properties of a laser.

According to an embodiment of the invention, a soft bake process may be performed after the step of forming the material layer on the substrate.

According to an embodiment of the invention, the method of forming the material layer on the substrate comprises at least one of the group of spin-coating, inkjet printing, drop-printing, casting, micro-contact, micro-stamp, screen printing, slot-die, and roll to roll printing.

According to an embodiment of the invention, the metal elements of the above organo-metallic compound comprise at least one of the groups comprising Ib, IIb, VIIIa Group elements, indium, tin, antimony, lead, bismuth or any combination thereof.

According to an embodiment of the invention, the substrate comprises at least one of the group comprising Si wafer, glass substrate, metal substrate or a plastic substrate.

According to an embodiment of the invention, a semiconductor layer is further formed on the substrate before or after forming the material layer. The material layer and semiconductor layer may be patterned simultaneously using the photochemical or heating properties of the laser.

According to an embodiment of the invention, the material of the semiconductor layer comprises at least one of the groups comprising small molecule, oligomer, polymer, or any other organic substance which can be transformed into semiconductor property.

The organo-metallic compound is patterned by utilizing the photochemical or heating properties of laser so that direct contact with the acid and alkaline solution used in the photolithography process may be avoided. Thus, damage of the organic semiconductor due to direct contact with the acid and alkaline solution may be effectively avoided and also the electrode may be fabricated with a greater precision compared to that using the ink-jet printing. Moreover, only the localized area is exposed to the heat of the laser, thus the whole substrate need not be subjected to the heat, which would otherwise adversely affect the properties of the device. Furthermore, as the laser patterning process is confined to local areas, therefore other elements of the device are unaffected by the laser patterning process. Therefore, current leakage may be effectively reduced.

In order to the make aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

FIGS. 1A-1E are sectional views illustrating the process steps of fabricating an electrode of a semiconductor device according to a first embodiment of the present invention.

FIGS. 2A-2D are sectional views illustrating the process steps of fabricating an electrode of a semiconductor device according to a second embodiment of the present invention.

FIGS. 3A-3D are sectional views illustrating the process steps of fabricating an electrode of a semiconductor device according to a third embodiment of the present invention.

FIGS. 4A-4D are structural sectional views of the four thin film transistors according to a fourth embodiment of the present invention.

### DESCRIPTION OF EMBODIMENTS

The concept of the present invention in fabricating an electrode of a semiconductor device includes utilizing the reaction between laser and a material layer, wherein the heating and photochemical properties, which varies according to the wavelength of the laser or the properties of the material or both. Thus, an electrode pattern with high precision may be obtained without the photolithography process. The application of the present invention may be illustrated using the following embodiments, but it is not intended to limit the present invention to the contents described in the embodiments.

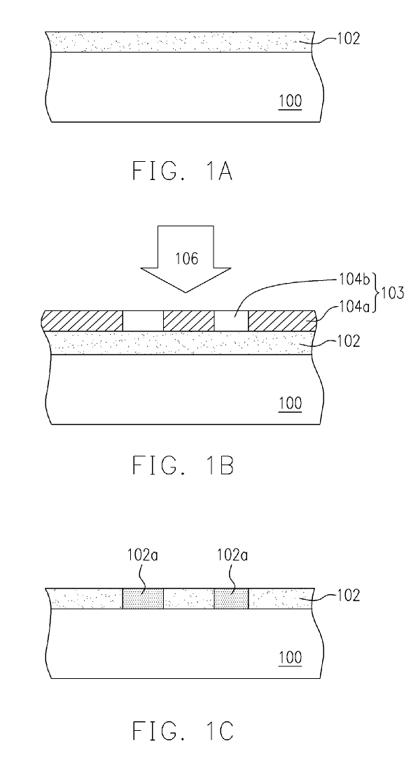

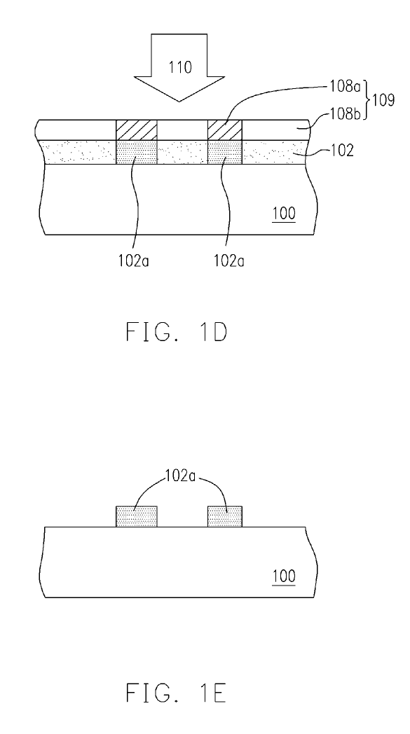

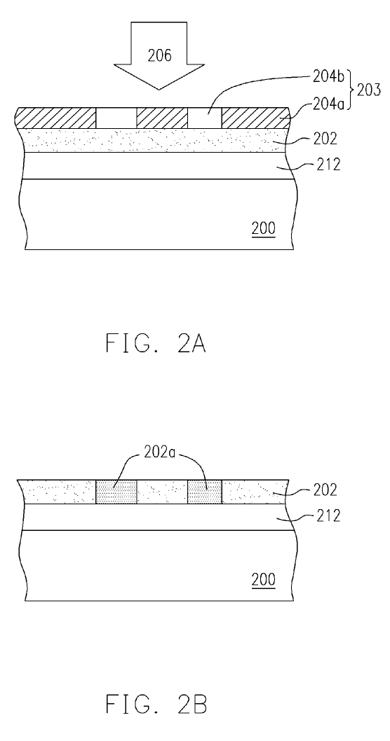

FIGS. 1A-1E are sectional views illustrating the process steps of fabricating an electrode of a semiconductor device according to a first embodiment of the present invention.

Referring to FIG. 1A, a material layer 102 is formed on a substrate 100, wherein the material layer 102 may comprise an organo-metallic compound, and the substrate 100 comprises at least one of the groups comprising Si wafer, glass substrate, metal substrate or plastic substrate. The method of forming the material layer 102 on the substrate 100 may include spin-coating, inkjet printing, drop-printing, casting, micro-contact, micro-stamp, screen printing, slot-die, or roll to roll printing. The metal elements of the organo-metallic compound layer may comprise at least one of the group comprising Ib, IIb, or VIIIa Group elements, for example, copper, silver, gold, zinc, cadmium, palladium, iridium, ruthenium, osmium, rhodium, platinum, iron, cobalt, nickel or the like, or also can comprise at least one of indium, tin, antimony, lead or bismuth, or further can be any combination of the foregoing elements.

Referring to FIG. 1B, the mask 103 with a non-transparent area 104a and a transparent area 104b is placed on the material layer 102, wherein area of the material layer 102 located below the transparent area 104b is adopted for forming the electrode of the semiconductor device. A laser 106 is used to irradiate the material layer 102.

Referring to FIG. 1C, when the material layer 102 comprises an organo-metallic compound layer, the electrical property of portion of the material layer 102 irradiated by the laser 106 is transformed into a conductive property due to the break of branched organic bond therein. That is, an electrode 102a is formed by locally irradiating a portion of the material layer 102 using the heating property of the laser 106. Thus, the electrode 102a with a high precision pattern may be obtained using the laser 106.

Referring to FIG. 1D, another mask 109 having a non-transparent area 108a and a transparent area 108b is placed on the material layer 102. Next, the resulting structure is irradiated with a laser, and a portion of the material layer 102 below the transparent area 108b is removed. Next, the material layer 102 is irradiated using a laser 110, whose wavelength may be identical or similar to the absorption wavelength of the material layer 102.

Finally, referring to FIG. 1E, the material layer 102 is patterned using the photochemical or heating properties of the laser 110 (shown in FIG. 1D) to a remaining portion of the material layer 102 leaving the electrode 102a intact. Next, the mask 109 is removed.

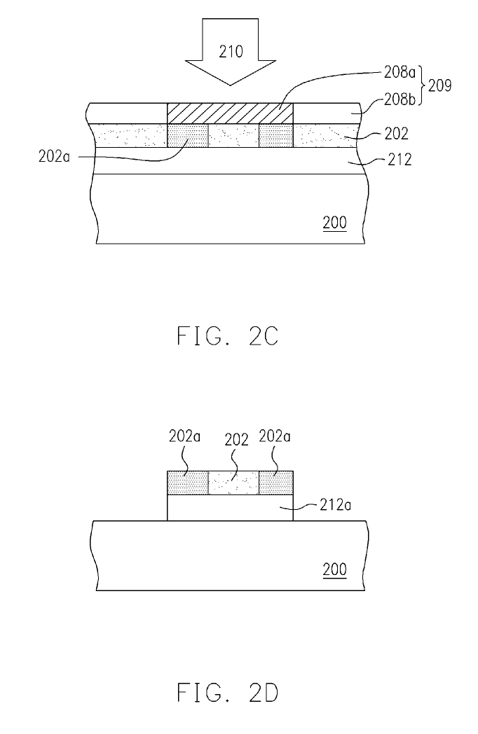

FIGS. 2A-2D are sectional views illustrating the process steps of fabricating an electrode of a semiconductor device according to a second embodiment of the present invention, which is similar to that of the first embodiment. Therefore, the reference numbers in this embodiment similar to that of the first embodiment indicate similar elements.

Referring to FIG. 2A, a semiconductor layer 212 is formed on a substrate 200, and then a material layer 202 is formed over the substrate 200. The material layer 202 can be various possible examples referred in the first embodiment (i.e., material layer 102), and the material of the semiconductor layer 212 includes the organic semiconductor material. The organic semiconductor material is, for example, small molecule, oligomer, polymer, or any other organic substance which can be transformed into semiconductor property. Next, a mask 203 having a non-transparent area 204a and a transparent area 204b is disposed on the material layer 202, and then the material layer 202 is irradiated using the laser 206 to form an electrode 202a.

Next, referring to FIG. 2B, the mask 203 is removed. Thus, the electrode 202a is formed by locally irradiating a portion of the material layer 202 using the laser 206.

Thereafter, referring to FIG. 2C, another mask 209 having a non-transparent area 208a and a transparent area 208b is disposed on the material layer 202. Then, the material layer 202 is irradiated using a laser 210 to pattern the material layer 202.

Then, referring to FIG. 2D, the material layer 202 is patterned by utilizing the photochemical or heating function of the laser, and the semiconductor layer 212 are simultaneously patterned to form a top contact electrode. Since the semiconductor layer 212a is also patterned, the current leakage between elements can be avoided. Finally, the mask 209 is removed.

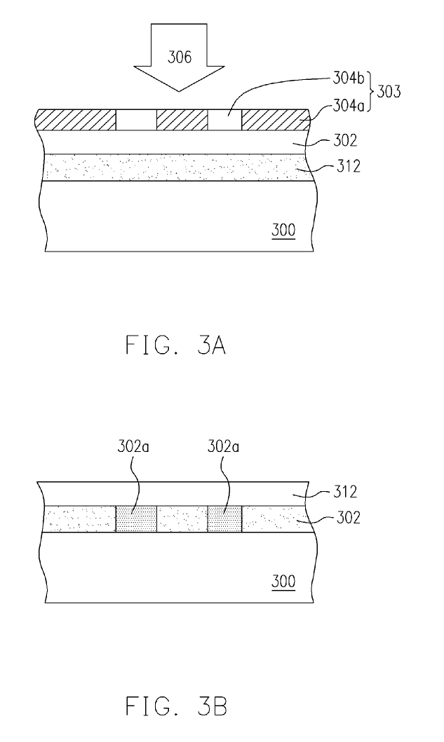

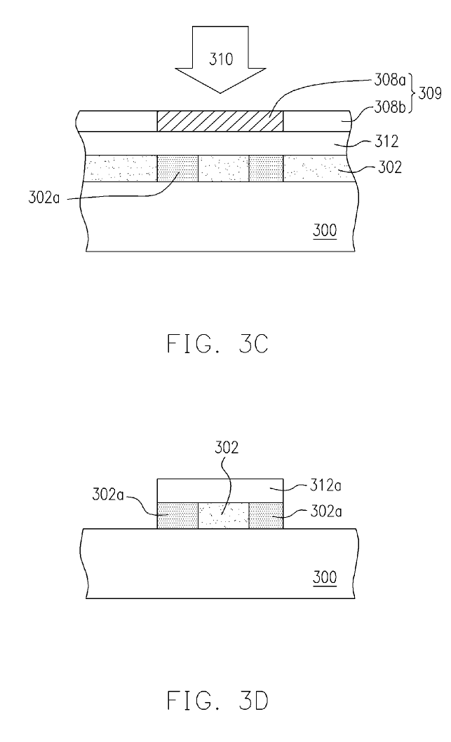

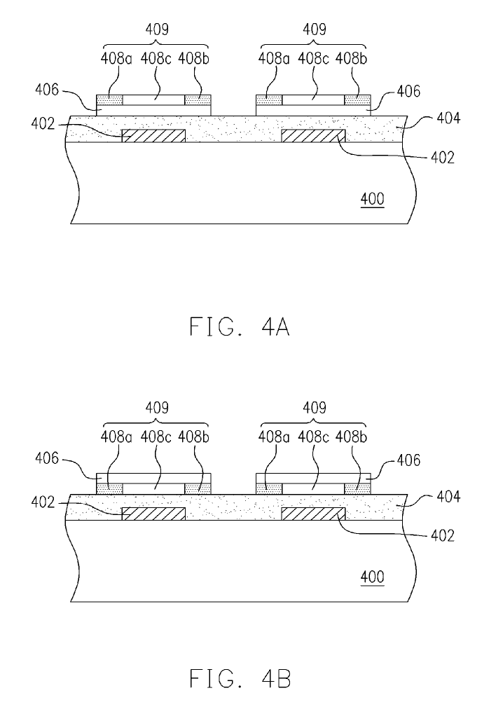

FIGS. 3A-3D are sectional views illustrating the process steps of fabricating an electrode of a semiconductor device according to a third embodiment of the present invention, which is similar to that of the second embodiment. Therefore, the reference numbers in this embodiment similar to that of the second embodiment indicate similar elements.

Referring to FIG. 3A, in this embodiment, after the material layer 302 is formed, a semiconductor layer 312 is then formed over the substrate 300. The examples of the material layer 302 and the semiconductor layer 312 can be similar to those exemplified in the above embodiments. Next, a mask 303 having a non-transparent area 304a and a transparent area 304b is disposed on the material layer 312, and then the semiconductor layer 312 and the material layer 302 are irradiated by the laser 306 to form an electrode 302a.

Next, referring to FIG. 3B, the mask 303 is removed. Thus, a portion of the material layer 302 may be locally irradiated with a laser to form the electrode 302a.

Next, referring to FIG. 3C, another mask 309 having a non-transparent area 308a and a transparent area 308b is disposed on the semiconductor layer 312. Next, the semiconductor layer 312 and the material layer 302 are irradiated by the laser 310.

Finally, referring to FIG. 3D, the semiconductor layer 312 and the material layer 302 are patterned simultaneously using the photochemical or heating properties of the laser form a bottom contact electrode. Thereafter, the mask 309 is removed.

It should be noted that the present invention may also be applied to manufacture electronic elements, such as, organic thin film transistor, organic solar cell. Thus, the present invention is suitable for the electronic products of large area, low cost, and soft substrate, such as active-matrix displays, smart cards, price tags, inventory tags, radio frequency identification (RFID), or large-Area Sensor arrays. The electronic elements manufactured according to the present invention can be integrated with various types of displays, e.g., OLED, PLED, EPD, LCD, and the like. The thin film transistor is taken as an example below.

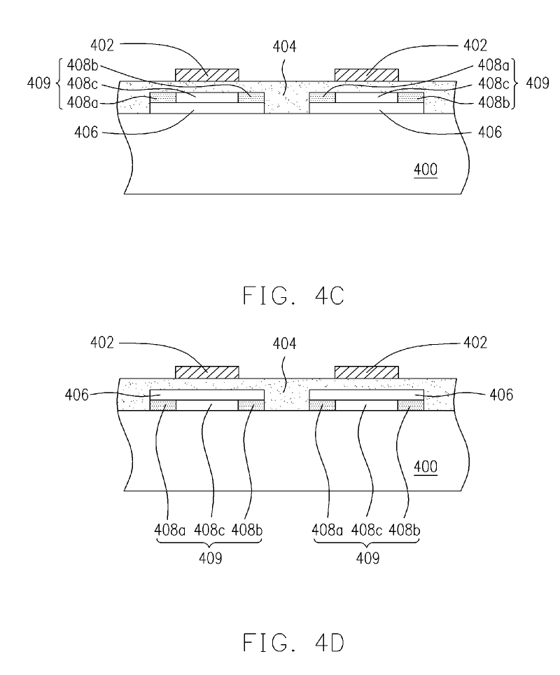

FIGS. 4A-4D are structural sectional views of the four thin film transistors according to a fourth embodiment of the present invention.

Referring to FIGS. 4A-4D, the thin film transistor of this embodiment comprises a substrate 400, a gate electrode 402, a gate insulator 404, a semiconductor layer 406, and a source electrode 408a and a drain electrode 408b. This thin film transistor is characterized in that the material of the gate electrode 402 and/or the source electrode 408a and the drain electrode 408b may comprise an organo-metallic compound whose electrical property is transformed into a conductive property using the techniques of laser irradiation described in the first, second and third embodiments above. Therefore, taking the source electrode 408a and the drain electrode 408b as an example, when they comprise the organo-metallic compound 409, the insulating property of the source electrode 408a and the drain electrode 408b may be transformed into the conductive property by irradiating them using the laser. On the other hand, the insulating property of the portions 408c of the source electrode 408a and the drain electrode 408b not irradiated by the laser remain unchanged. Furthermore, the thin film transistor in this embodiment includes the bottom gate with top contact thin film transistor (shown in FIG. 4A), the bottom gate with bottom contact thin film transistor (shown in FIG. 4B), the top gate with top contact thin film transistor (shown in FIG. 4C), the top gate with bottom contract thin film transistor (shown in FIG. 4D).

Referring to FIGS. 4A-4D, the semiconductor layer 406 may be located above the source electrode 408a and the drain electrode 408b, as shown in FIGS. 4B and 4D. Or it may also be located below the source electrode 408a and the drain electrode 408b, as shown in FIGS. 4A and 4C. Additionally, the source electrode 408a and the drain electrode 408b may also be selectively located above both sides of the gate electrode 402 respectively, as shown in FIGS. 4A and 4B, or below both sides of the gate electrode 402, as shown in FIGS. 4C and 4D. The gate insulation layer 404 is adopted to separate the gate electrode 402 and the semiconductor layer 406, and the source electrode 408a and the drain electrode 408b. Furthermore, for example, the metal elements of the organo-metallic compound comprise at least one of the group comprising Ib, IIb, or VIIIa Group elements such as copper, silver, gold, zinc, cadmium, palladium, iridium, ruthenium, osmium, rhodium, platinum, iron, cobalt, nickel or the like, or also can comprise at least one of the group comprising indium, tin, antimony, lead or bismuth, or further can be any combination of the foregoing elements. Also, the material of the above gate insulation layer 404 comprises organic material or inorganic material, wherein the organic material includes, for example, polymethyl methacrylate (PMMA), polyvinyl alcohol (PVA), polyvinyl phenol (PVP), polyimide (PI), and the like; the inorganic material includes, for example, SiOx, SiNx, LiF, and the like. Additionally, a self-assembling material (SAM), or a interlayer material can be deposited on the insulation layer 404, such that the molecules can be arranged better, thus improving the mobility of the carriers.

In summary, the present invention is characterized in that the organo-metallic compound is irradiated by a laser to transform into a conductive material and used as an electrode of a semiconductor device. Thus, the electrode may be avoided from coming direct contact with the acid and alkaline solution as in the case of the photolithography process. Therefore, damage to the electrode the acid and alkaline solution may be effectively avoided. Furthermore, since the material layer containing organo-metallic compound is irradiated by a laser so that the organo-metallic compound is transformed into a conductive material and is used to serve as the electrode and the material layer is patterned using a laser, and therefore an electrode pattern with a greater precision may be obtained compared to that obtained using ink-jet printing. It should be noted that the property of the portion of the layer containing organo-metallic compound not irradiated by the laser will remain unchanged and it will still retain its insulating property, and consequently current leakage problem may be resolved. Moreover, the laser irradiation process is localized to predetermined areas, so the whole substrate need not be subjected to heat. Thus, other elements on the substrate may be unaffected. Furthermore, because patterning process is also performed using the laser, therefore it can be carried out without adversely affecting other elements. Thus, current leakage problems may also be avoided. In addition, the material layer containing organo-metallic compound and the semiconductor layer containing organic material may be continuously coated, thus the patterning process may be reduced. The fabrication throughput using the laser is substantially higher than that using the ink-jet printing process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electrode of a semiconductor device comprising an organo-metallic compound that is transformed from an insulator into a conductor through the heating process of laser.

2. The device electrode as claimed in claim 1, wherein the metal elements in the organo-metallic compound comprise at least one of the group comprising Ib, IIb, VIIIa Group elements, indium, tin, antimony, lead, bismuth, or any combination thereof.

3. A thin film transistor, comprising a substrate, a gate electrode, a gate insulation layer, a semiconductor layer, a source electrode and a drain electrode, wherein:
the semiconductor layer is disposed over or under the source electrode and the drain electrode;
the source electrode and the drain electrode are disposed over or below the gate electrode;
the gate insulation layer is used for separating the gate electrode and the semiconductor layer, the source electrode and the drain electrode; and
the thin film transistor is characterized in that:
the materials of the gate electrode and/or the source electrode and the drain electrode comprise an organo-metallic compound that is transformed from an insulator into a conductor through the heating process of laser.

4. The thin film transistor as claimed in claim 3, wherein the metal elements of the organo-metallic compound comprise at least one of the group comprising Ib, IIb, VIIIa Group elements, indium, tin, antimony, lead, bismuth or any combination thereof.

5. The thin film transistor as claimed in claim 3, wherein the material of the semiconductor layer comprises an organic semiconductor material.

6. The thin film transistor as claimed in claim 5, wherein the organic semiconductor material comprises at least one of the group comprising small molecule, oligomer, polymer, or any other organic substance which can be transformed into semiconductor property.

7. The thin film transistor as claimed in claim 3, wherein the substrate comprises at least one of the group comprising Si wafer, glass substrate, metal substrate and plastic substrate.

8. The thin film transistor as claimed in claim 3, wherein the material of the gate insulation layer comprises an organic material or an inorganic material.

9. The thin film transistor as claimed in claim 8, wherein the organic material comprises polymethyl methacrylate (PMMA), polyvinyl alcohol (PVA), polyvinyl phenol (PVP) or polyimide (PI); and the inorganic material comprises SiOx, SiNx, or LiF.

10. A method of forming an electrode of a semiconductor device, comprising:
forming a material layer over a substrate, wherein the material layer comprises an organo-metallic compound layer;
forming an electrode by irradiating the material layer through utilizing the heating property of laser; and
patterning the material layer by utilizing the photochemical or heating properties of laser.

11. The method of forming an electrode of a semiconductor device as claimed in claim 10, further comprising a soft bake process after the step of forming the material layer over the substrate.

12. The method of forming an electrode of a semiconductor device as claimed in claim 10, wherein the step of forming the material layer over the substrate comprises at least one of the group comprising spin-coating, inkjet printing, drop-printing, casting, micro-contacting, micro-stamping, screen printing, slot-dieing and roll to roll printing.

13. The method of forming an electrode of a semiconductor device as claimed in claim 10, wherein the metal elements of the organo-metallic compound comprise at least one of the groups comprising Ib, IIb, VIIIa Group elements, indium, tin, antimony, lead, bismuth or any combination thereof.

14. The method of forming an electrode of a semiconductor device as claimed in claim 10, wherein the substrate comprises at least one of the group comprising Si wafer, glass substrate, metal substrate and plastic substrate.

15. The method of forming an electrode of a semiconductor device as claimed in claim 10, further comprising forming a semiconductor layer on the substrate before or after the step of forming the material layer.

16. The method of forming an electrode of a semiconductor device as claimed in claim 15, wherein the material layer and the semiconductor layer are patterned simultaneously.

17. The method of forming an electrode of a semiconductor device as claimed in claim 15, wherein the material of the semiconductor layer comprises an organic semiconductor material.

18. The method of forming an electrode of a semiconductor device as claimed in claim 17, wherein the organic semiconductor material comprises at least one of the groups comprising small molecule, oligomer, polymer, or any other organic substance which can be transformed into semiconductor property.

19. A method of forming a thin film transistor comprising forming an electrode using the method as claimed in claim 10.
